(19) United States
(12) Patent Application Publication
(10) Pub. No.: US 2010/0181105 A1
(43) Pub. Date: Jul. 22, 2010

(54) PACKAGE FOR ELECTRON ELEMENT AND ELECTRONIC COMPONENT

(75) Inventors: Takuma Hitomi, Osaka (JP); Masanori Hongo, Osaka (JP); Hideki Ito, Osaka (JP); Kiyoshi Yamakoshi, Osaka (JP); Masami Fukuyama, Osaka (JP); Hideki Takagi, Osaka (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignees: SANYO ELECTRIC CO., LTD., Osaka (JP); SANYO TUNER INDUSTRIES CO., LTD., Osaka (JP)

(21) Appl. No.: 12/690,223

(22) Filed: Jan. 20, 2010

(30) Foreign Application Priority Data
Jan. 22, 2009 (JP) 2009-011580

(51) Int. Cl. H05K 1/11

(52) U.S. Cl. 174/266

(57) ABSTRACT

A package for an electron element comprises: a base substrate made of ceramic; a frame body made of ceramic arranged on a top surface of the base substrate and provided therein with a cavity for accommodating the electron element; a via formed in the base substrate below the cavity, penetrating the base substrate from the top surface to a bottom surface thereof and filled with a thermally-conductive material; and a projecting part formed on an inner wall of the via and projecting toward a center of the via. The projecting part has a length along a direction perpendicular to a penetration direction of the via not less than a thickness along the penetration direction. An electronic component comprises the package and the electron element mounted thereon. The electron element is accommodated in the cavity defined inside the frame body of the package and arranged above the via.

The application Number 2009-011580, upon which this patent application is based, is hereby incorporated by reference.

### BACKGROUND OF THE INVENTION

1. Field of the Invention

The present invention relates to a package for mounting thereon an electron element such as a light emitting element, an integrated circuit or the like (a package for an electron element), and to an electronic component comprising the package for the electron element.

2. Description of Related Art

Conventionally, a package for mounting a light emitting element thereon (a package for a light emitting element) is formed by a base substrate and a frame body each made of ceramic which are integrally bonded together. The frame body has a cavity defined therein for accommodating the light emitting element.

The base substrate made of ceramic can be provided with a thermal via formed therein. In a package for the light emitting element including the base substrate provided with the thermal via formed therein, it is possible to dissipate heat of the light emitting element accommodated in the cavity to the outside. The thermal via is formed by filling a thermally-conductive material in a via opening through the base substrate.

In the package including the thermal via penetrating the base substrate made of ceramic from a top surface to a bottom surface thereof to be exposed to the cavity, the heat of the light emitting element accommodated in the cavity transfers toward the bottom surface of the base substrate through the thermal via, and a part of the heat is diffused in the base substrate. As a result, a trouble of the light emitting element due to the heat hardly occurs.

However, the thermally-conductive material forming the thermal via has a lower bending strength than that of ceramic. Therefore, in the case where the thermal via is formed in the base substrate, although the package exhibits high heat dissipation properties, the package exhibits low bending strength.

### SUMMARY OF THE INVENTION

In view of above described problem, an object of the present invention is to obtain both of high heat dissipation properties and high bending strength in a package for mounting thereon the electron element such as the light emitting element, the integrated circuit or the like, and an electronic component comprising the package for the electron element.

A first package for an electron element according to the present invention comprises: a base substrate made of ceramic; a frame body made of ceramic arranged on a top surface of the base substrate and provided therein with a cavity for accommodating the electron element; a via formed in the base substrate below the cavity, penetrating the base substrate from the top surface to a bottom surface thereof, and filled with a thermally-conductive material; and a projecting part formed on an inner wall of the via and projecting toward a center of the via. The projecting part has a length along a direction perpendicular to a penetration direction of the via not less than a thickness along the penetration direction.

In the package for the electron element described above, the projecting part formed on the inner wall of the via projects into the thermally-conductive material filled in the via. The base substrate and the thermally-conductive material contract in a firing process in producing the package for the electron element. However, they contract with different contraction ratios, and therefore, the thermally-conductive material and the projecting part projecting into the thermally-conductive material will be engaged with each other in the package for the electron element after firing.

Also, in the package for the electron element described above, since the projecting part has the length along the direction perpendicular to the penetration direction of the via not less than the thickness thereof along the penetration direction, the thermally-conductive material and the projecting part are strongly engaged with each other.

Accordingly, even in the case where the via is formed in the base substrate, a decrease in the bending strength of the base substrate is inhibited, and as a result, maintained is the high bending strength of the package for the electron element.

Further, in the package for the electron element described above, in the case where the electron element is accommodated in the cavity of the frame body, the heat generated from the electron element transfers toward the bottom surface of the base substrate through the thermally-conductive material filled in the via, and a part of the heat is diffused in the base substrate made of ceramic. Therefore, obtained are high heat dissipation properties of the package for the electron element.

A second package for an electron element according to the present invention is the first package for the electron element described above, wherein the projecting part is formed at both a top end position and a bottom end position of the inner wall of the via, and the via is narrower at the positions where the projecting parts are formed.

A third package for an electron element according to the present invention is the first or second package for the electron element described above, wherein the projecting part is formed in each of two side surface wall parts facing each other of the inner wall of the via, and the projecting part formed in one of the two side surface wall parts is displaced from the projecting part formed in the other side surface wall part in the penetration direction.

A fourth package for an electron element according to the present invention is the third package for the electron element described above, wherein the via has a cross-sectional area perpendicular to the penetration direction which is generally constant from a top end position to a bottom end position of the via. The heat generated from the electron element thereby easily transfers to the bottom surface of the base substrate through the thermally-conductive material filled in the via, resulting in higher heat dissipation properties of the package for the electron element.

A fifth package for an electron element according to the present invention is one of the first to fourth packages for the electron element described above, wherein the base substrate is produced by stacking a plurality of ceramic sheets and firing the ceramic sheets stacked, and the projecting part has a length not less than a thickness of one of the plurality of ceramic sheets.

An electronic component according to the present invention comprises one of the first to fifth packages for the electron element described above, and an electron element mounted on the package for the electron element. The electron element is accommodated in the cavity defined inside the frame body of the package for the electron element and arranged above the via.

### BRIEF DESCRIPTION OF THE DRAWINGS

FIG. 1 is a cross-sectional view of a ceramic body to be used for manufacturing a light emitting device according to an embodiment of the present invention;

FIG. 2 is a cross-sectional view of a package for a light emitting element produced by firing the ceramic body;

FIG. 3 is a cross-sectional view of the package for the light emitting element with the light emitting element installed therein;

FIG. 4 is a cross-sectional view of a produced light emitting device;

FIG. 5 is a cross-sectional view showing an example of the package for the light emitting element having a via with a varying cross-sectional area;

FIG. 6 is a cross-sectional view of the ceramic body to be used for manufacturing the package for the light emitting element of the example shown in FIG. 5;

FIG. 7 is a cross-sectional view showing another example of the package for the light emitting element having a via with a varying cross-sectional area;

FIG. 8 is a cross-sectional view of the ceramic body to be used for manufacturing the package for the light emitting element of the example shown in FIG. 7;

FIG. 9 is a cross-sectional view showing a further example of the package for the light emitting element having a via with a varying cross-sectional area; and

FIG. 10 is a cross-sectional view of the ceramic body to be used for manufacturing the package for the light emitting element of the example shown in FIG. 9.

### DETAILED DESCRIPTION OF THE PREFERRED EMBODIMENT

In a preferred embodiment discussed in detail below with reference to drawings, the present invention is implemented in a package for mounting a light emitting element thereon (a package for a light emitting element) and a light emitting device comprising the package for the light emitting element.

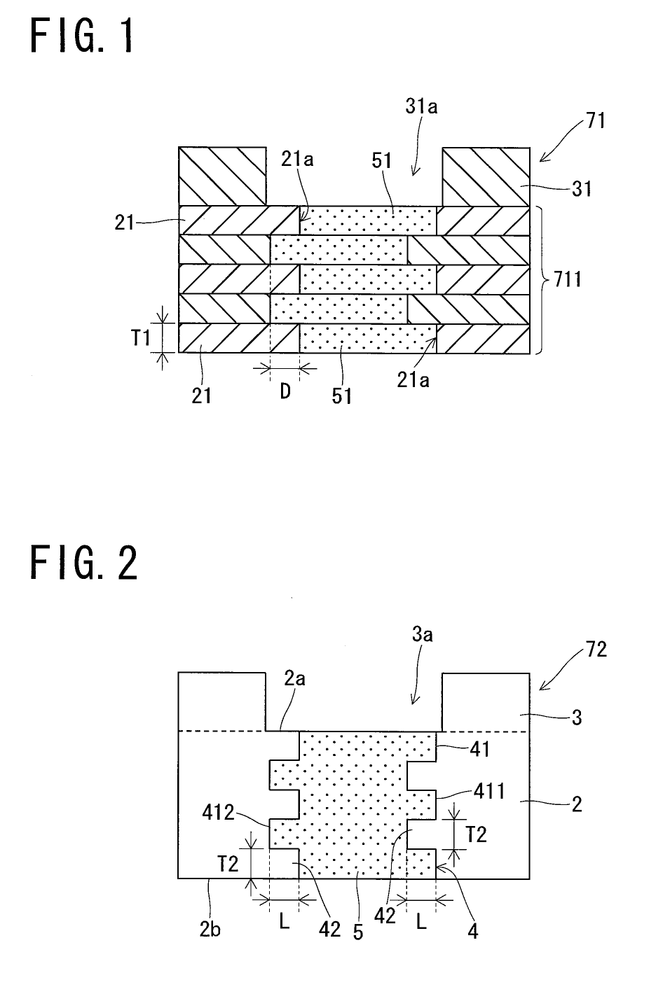

FIGS. 1 to 4 are cross-sectional views showing a manufacturing method of a light emitting device according to an embodiment of the present invention in the order of steps in the manufacturing process.

First, in a ceramic body forming step, as shown in FIG. 1, by stacking a plurality of ceramic sheets 21 made of ceramic, a stacked body 711 of the ceramic sheets 21 is formed. Each of the plurality of ceramic sheets 21 is provided with a through-hole 21a filled with a filling material 51. Cross-section shapes (not shown) of the through-holes 21a perpendicular to a passing-through direction of the through-hole 21a are generally the same among all of the ceramic sheets 21 stacked.

For the filling material 51, employed is a metal such as silver (Ag), copper (Cu) or the like which has a high heat conductivity. For ceramic forming the ceramic sheets 21, employed is a low temperature co-fired ceramic (LTCC) which can be simultaneously fired with the filling material 51.

As shown in FIG. 1, when stacking the ceramic sheets 21, adjacent ceramic sheets 21, 21 are arranged so that the through-holes 21a, 21a included therein are displaced from each other by a predetermined distance D along a direction perpendicular to a stacking direction and parts of the through-holes 21a, 21a overlap with each other. Here, the predetermined distance D is a distance not less than a thickness T1 of the ceramic sheet 21.

In particular, in a n-th ceramic sheet 21 stacked at a n-th position (n is an integer of 2 or larger) and a (n−1)th ceramic sheet 21 which is adjacent to the n-th ceramic sheet and placed on a lower side thereof, the through-hole 21a included in the n-th ceramic sheet 21 is displaced from the through-hole 21a included in the (n−1)th ceramic sheet 21 by the predetermined distance D in a single direction perpendicular to the stacking direction. In contrast, in the n-th ceramic sheet 21 and a (n+1)th ceramic sheet 21 which is adjacent to the n-th ceramic sheet 21 and placed on an upper side thereof, the through-hole 21a included in the (n+1)th ceramic sheet 21 is displaced from the through-hole 21a included in the n-th ceramic sheet 21 by the predetermined distance D in a direction opposite to said single direction.

Therefore, a part of the n-th ceramic sheet 21 projects by the predetermined distance D in said single direction perpendicular to the stacking direction with respect to the inner walls of the through-holes 21a, 21a included in the (n−1)th and (n+1)th ceramic sheets 21, 21, while a part of the (n+1)th ceramic sheet 21 projects by the predetermined distance D in the direction opposite to said single direction with respect to the inner walls of the through-holes 21a, 21a included in the n-th and a (n+2)th ceramic sheets 21, 21.

After forming the stacked body 711, a frame forming body 31 made of ceramic is disposed on a top surface of the stacked body 711. At this time, the frame forming body 31 is arranged on the top surface of the stacked body 711 so that the filling material 51 filled in the through-hole 21a of the ceramic sheet 21 placed at an uppermost layer of the stacked body 711 is exposed to a space 31a defined inside the frame forming body 31. A ceramic body 71 is thereby formed by the stacked body 711 and the frame forming body 31.

For ceramic forming the frame forming body 31, employed is the low temperature co-fired ceramic (LTCC) which can be simultaneously fired with the filling material 51. The ceramic forming the frame forming body 31 may be the same as or different from one that forms the ceramic sheet 21.

Next, in a firing step, the ceramic body 71 formed in the ceramic body forming step is fired to form a package for a light emitting element 72 shown in FIG. 2. By firing the ceramic body 71, the stacked body 711 and the frame forming body 31 are sintered to form a base substrate 2 and a frame body 3 respectively, and the base substrate 2 and the frame body 3 are integrally bonded together as shown in FIG. 2.

Also, due to sintering of the stacked body 711, the through-holes 21a of the ceramic sheets 21 forming the stacked body 711 are coupled to each other to become a via 4 penetrating the base substrate 2 from a top surface 2a to a bottom surface 2b thereof. Also, due to sintering of the frame forming body 31, the space 31a defined inside the frame forming body 31 becomes a cavity 3a for accommodating a light emitting element 1.

Further, due to sintering of the ceramic body 71, the filling materials 51 filled in the through-holes 21a of the ceramic sheets 21 are also sintered and integrated, and become a thermally-conductive material 5 filled in the via 4.

In this embodiment, the low temperature co-fired ceramic (LTCC) is used as the ceramic forming the ceramic body 71, and therefore, it is possible to sinter the ceramic at a temperature of 800 to 950 degrees C. Accordingly, it is possible to sinter the filling material 51, while inhibiting abnormal contraction or the like of a metal used for the filling material 51.

A ceramic part and the filling materials 51 of the ceramic body 71 both contract by sintering. However, since the ceramic part and the filling materials 51 of the ceramic body are made of different materials, they have different contraction ratios.

As described above, in the ceramic body 71, a part of the n-th ceramic sheet 21 projects by the predetermined distance D in the single direction perpendicular to the stacking direction, and a part of the (n+1)th ceramic sheet 21 projects by the predetermined distance D in the direction opposite to the single direction. Therefore, as shown in FIG. 2, in the package 72, a projecting part 42 projecting toward a center of the via 4 is formed at each of two side surface wall parts 411, 412 facing each other of an inner wall 41 of the via 4. Accordingly, the ceramic forming the base substrate 2 projects from the inner wall 41 of the via 4 into the thermally-conductive material 5 filled in the via 4.

Since the ceramic part and the filling materials 51 of the ceramic body 71 contract with different contraction ratios in firing, the thermally-conductive material 5 and the projecting parts 42 projecting into the thermally-conductive material 5 are engaged with each other in the package 72 after firing.

Further, in the unfired ceramic body 71, the predetermined distance D is a distance not less than the thickness T1 of the ceramic sheet 21, and therefore, in the package 72, the projecting part 42 has a length L along a direction perpendicular to a penetration direction of the via 4 which is not less than a thickness T2 along the penetration direction. Accordingly, the thermally-conductive material 5 and the projecting part 42 are strongly engaged with each other.

Here, the length L and the thickness T2 are respectively smaller than the predetermined distance D and the thickness T1 by an amount corresponding to the contraction of the ceramic body 71. Therefore, the length L of the projecting part 42 is not less than the thickness T1 of the ceramic sheet 21.

In the package 72 according to this embodiment, the projecting part 42 formed in the one side surface wall part 411 and the projecting part 42 formed in the other side surface wall part 412 are displaced from each other along the penetration direction.

With the package 72 described above, since the thermally-conductive material 5 and the projecting part 42 are strongly engaged with each other as described above, a decrease in the bending strength of the base substrate 2 is inhibited even in the case where the via 4 is formed in the base substrate 2, and as a result, maintained is the high bending strength of the package 72. Also, with the structure shown in FIG. 2, enhanced is not only the bending strength which is a static strength, but also a dynamic strength against a strain stress.

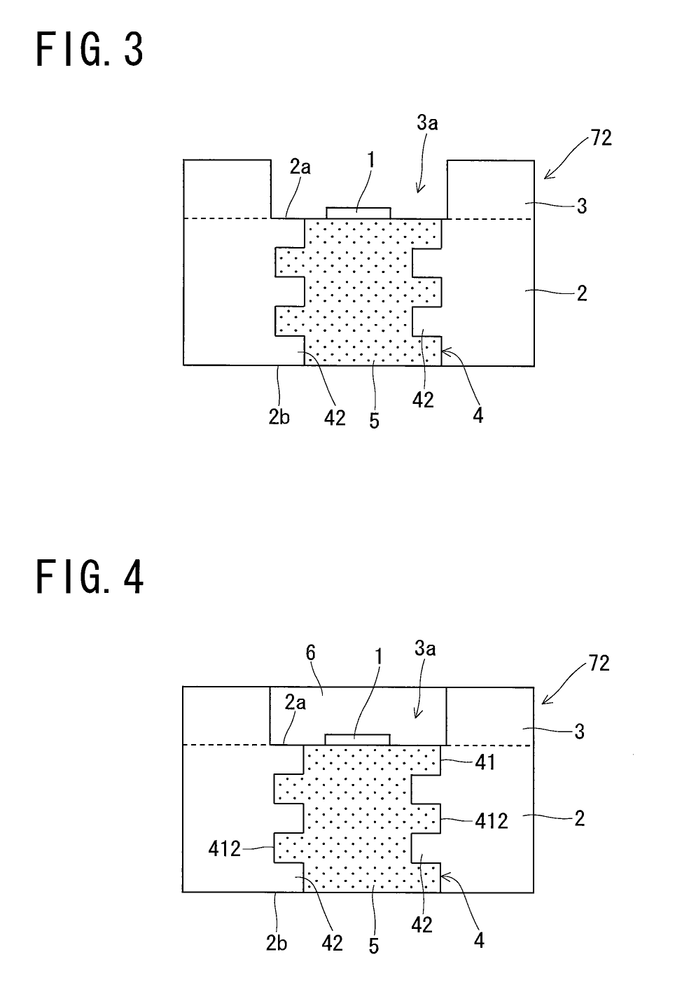

Next, in a light emitting element installation step, as shown in FIG. 3, the light emitting element 1 is installed in the package 72 produced in the firing step. In particular, the light emitting element 1 is installed in the cavity 3a at a position above the via 4, namely, in an area of the top surface 2a of the base substrate 2 where the thermally-conductive material 5 is exposed.

And then, in a resin filling step, as shown in FIG. 4, a resin 6 including a fluorescent material is filled in the cavity 3a, and the resin 6 is hardened. A light emitting device according to this embodiment of the present invention is thereby produced.

In the light emitting device thereby produced, the heat generated from the light emitting element 1 transfers toward the bottom surface 2b of the base substrate 2 through the thermally-conductive material 5 filled in the via 4, and a part of the heat is diffused in the base substrate 2 made of ceramic.

Further, in this embodiment, among all the ceramic sheets forming the unfired ceramic body 71, the cross-section shapes of the through-holes 21a are generally the same. Therefore, as shown in FIG. 4, in the package 72, the cross-sectional area of the via 4 perpendicular to the penetration direction is generally constant from a top end position to a bottom end position of the via 4. Therefore, the heat generated from the light emitting element 1 easily transfers to the bottom surface 2b of the base substrate 2 through the thermally-conductive material 5 filled in the via 4.

Accordingly, it is possible to obtain the high heat dissipation properties in the light emitting device comprising the package 72 described above.

Accordingly, with the package 72 described above, it is possible to obtain both the high heat dissipation properties and the high bending strength.

The heat dissipation properties of the package 72 depends on not only the cross-sectional area of the via 4, but also a volume thereof. The greater the volume of the via 4 is, the higher the heat dissipation properties of the package 72 becomes. Therefore, even in the case where the cross-sectional area of the via 4 is not generally constant from the top end position to the bottom end position of the via 4, it is also possible to obtain sufficient heat dissipation properties in the package 72 by adjusting the volume of the via 4.

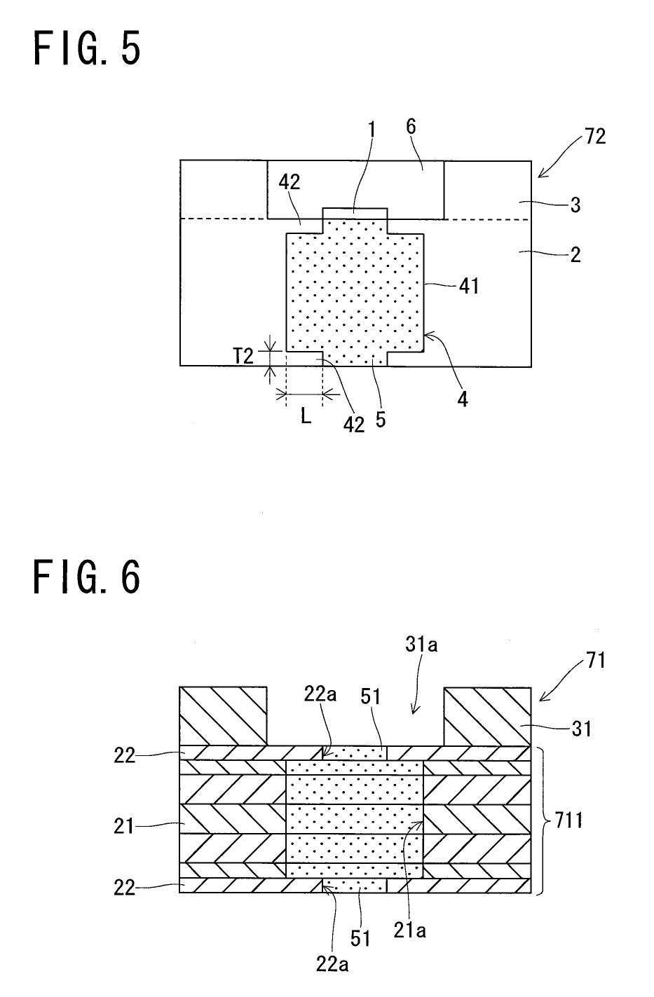

FIG. 5 is a cross-sectional view of an example of the light emitting device comprising the package 72 having the via 4 with a varying cross-sectional area. In the package 72 shown in FIG. 5, the projecting part 42 is formed on the inner wall 41 of the via 4 at both the top end position and the bottom end position of the via 4, and the via 4 is narrower at the positions where the projecting parts 42 are formed.

Here, as to any of the projecting parts 42, the length L along the direction perpendicular to the penetration direction of the via 4 is not less than the thickness T2 along the penetration direction.

In the package 72 described above, the thermally-conductive material 5 is placed between the projecting part 42 projecting at the top end position and the projecting part 42 projecting at the bottom end position, whereby the thermally-conductive material 5 and the projecting parts 42 are engaged with each other. Therefore, with this package 72, a decrease in the bending strength of the base substrate 2 is inhibited even in the case where the via 4 is formed in the base substrate 2 in a similar manner to in the package 72 shown in FIG. 2, and as a result, maintained is the high bending strength of the package 72.

The package 72 shown in FIG. 5 is produced by firing the ceramic body 71 shown in FIG. 6. The ceramic body 71 shown in FIG. 6 is formed by stacking ceramic sheets 21, 22 of two different types having through-holes 21a, 22a with different cross-sectional areas perpendicular to the passing-through direction.

In particular, one ceramic sheet 22 having the through-hole 22a with the smaller cross-sectional area is placed at positions of an uppermost layer and a lowermost layer. And between these ceramic sheets 22, stacked are the plurality of the other ceramic sheets 21 having the through-holes 21a with the larger cross-sectional area. The filling material 51 filled in the through-hole 22a of the one ceramic sheet 22 overlaps with a central part of the filling material 51 filled in the through-hole 21a of the other ceramic sheet 21, while the one ceramic sheet 22 overlaps with a part of the filling material 51 around the central part.

In the ceramic body 71 shown in FIG. 6, the one ceramic sheet 22 is thinner than the other ceramic sheet 21.

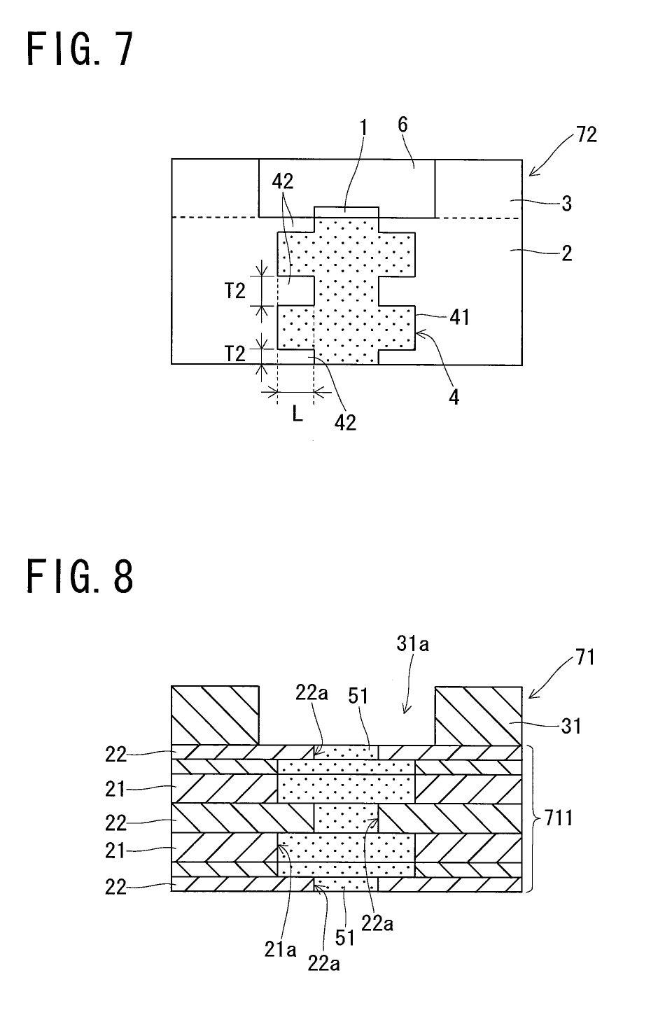

FIG. 7 is a cross-sectional view showing another example of the light emitting device comprising the package 72 having the via 4 with a varying cross-sectional area. The package 72 shown in FIG. 7 is the package 72 shown in FIG. 5, in which the projecting part 42 projects not only at the top end position and the bottom end position of the via 4, but also at a position between the top end position and the bottom end position of the via 4. Here, the via 4 is narrower at the positions where the projecting parts 42 are formed.

Here, as to any of the projecting parts 42, the length L along the direction perpendicular to the penetration direction of the via 4 is not less than the thickness T2 along the penetration direction.

With the package 72 described above, since the projecting part 42 is formed also at the position between the projecting part 42 projecting at the top end position and the projecting part 42 projecting at the bottom end position, the thermally-conductive material 5 and the projecting parts 42 are engaged with each other strongly compared to the package 72 shown in FIG. 5. Therefore, with the package 72 shown in FIG. 7, a decrease in the bending strength of the base substrate 2 is inhibited even in the case where the via 4 is formed in the base substrate 2 in a similar manner to in the package 72 shown in FIG. 2, and as a result, maintained is the high bending strength of the package 72.

The package 72 shown in FIG. 7 is produced by firing the ceramic body 71 shown in FIG. 8. The ceramic body 71 shown in FIG. 8 is the ceramic body 71 shown in FIG. 6, further including the one ceramic sheet 22 having the through-hole 22a with the smaller cross-sectional area arranged also at an intermediate position between the uppermost layer and the lowermost layer. Here, the plurality of the other ceramic sheets 21 having the through-holes 21a with the larger cross-sectional area are stacked among the three ceramic sheets 22.

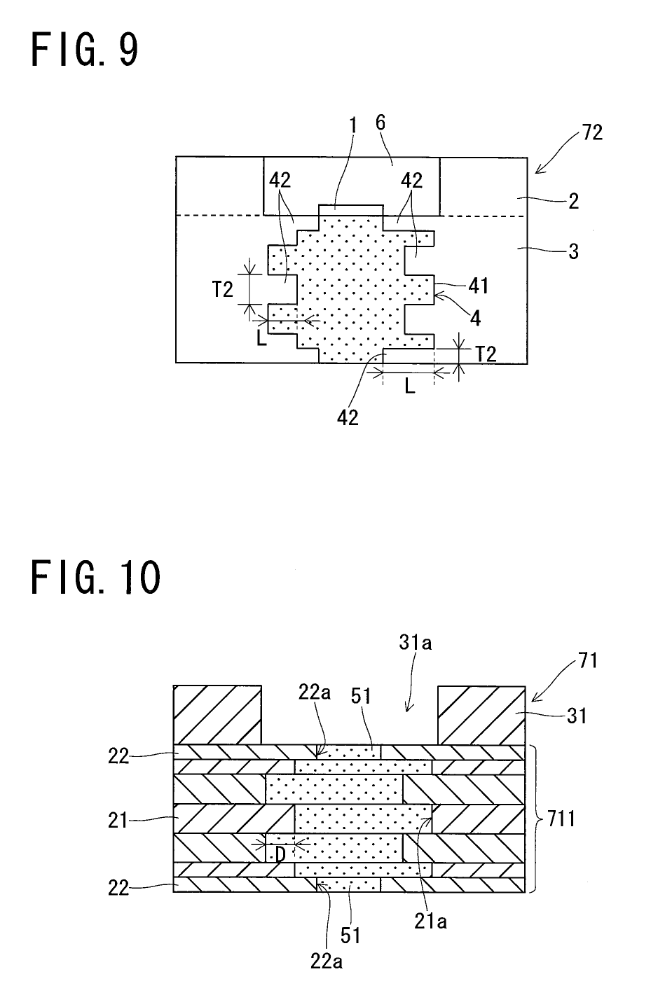

FIG. 9 is a cross-sectional view showing a further example of the light emitting device comprising the package 72 having the via 4 with a varying cross-sectional area. The package 72 shown in FIG. 9 is the package 72 shown in FIG. 5, in which the projecting part 42 is formed not only at the top end position and the bottom end position of the via 4, but also at a position between the top end position and the bottom end position of the via 4. Here, although the via 4 is narrower at the top end position and the bottom end position, the cross-sectional area of the via 4 is generally the same at the position between the top end position and the bottom end position.

Here, as to any of the projecting parts 42, the length L along the direction perpendicular to the penetration direction of the via 4 is not less than the thickness T2 along the penetration direction.

With the package 72 described above, since the projecting part 42 is formed also at the position between the projecting part 42 projecting at the top end position and the projecting part 42 projecting at the bottom end position, the thermally-conductive material 5 and the projecting parts 42 are engaged with each other strongly compared to the package 72 shown in FIG. 5. Therefore, with the package 72 shown in FIG. 9, a decrease in the bending strength of the base substrate 2 is inhibited even in the case where the via 4 is formed in the base substrate 2 in a similar manner to in the package 72 shown in FIG. 2, and as a result, maintained is the high bending strength of the package 72.

The package 72 shown in FIG. 9 is produced by firing the ceramic body 71 shown in FIG. 10. The ceramic body 71 shown in FIG. 10 is the ceramic body 71 shown in FIG. 6, in which the through-holes 21a of the other ceramic sheets 21 which are stacked on one another are displaced from each other in the direction perpendicular to the stacking direction by the predetermined distance D in a similar manner to in the ceramic body 71 shown in FIG. 1.

The present invention is not limited to the foregoing embodiment in construction but can be modified variously within the technical range set forth in the appended claims. For example, as long as the length L of the projecting part 42 is not less than the thickness T2, the arrangement or shape of the projecting part 42 formed on the inner wall 41 of the via 4 is not limited by that in the foregoing embodiment.

In the foregoing embodiment, the present invention is applied to the package for the light emitting element. However, the present invention is not limited to this, but can be applied to various packages for mounting the electron element such as integrated circuit or the like thereon (packages for the electron element).

What is claimed is:

1. A package for an electron element comprising:
a base substrate made of ceramic;
a frame body made of ceramic arranged on a top surface of the base substrate and provided therein with a cavity for accommodating the electron element;
a via formed in the base substrate below the cavity, penetrating the base substrate from the top surface to a bottom surface thereof, and filled with a thermally-conductive material; and
a projecting part formed on an inner wall of the via and projecting toward a center of the via,
wherein the projecting part has a length along a direction perpendicular to a penetration direction of the via not less than a thickness along the penetration direction.

2. The package for the electron element according to claim 1, wherein the projecting part is formed at both a top end position and a bottom end position of the inner wall of the via, and the via is narrower at the positions where the projecting parts are formed.

3. The package for the electron element according to claim 1, wherein the projecting part is formed in each of two side surface wall parts facing each other of the inner wall of the via, and the projecting part formed in one of the two side surface wall parts is displaced from the projecting part formed in the other side surface wall part in the penetration direction.

4. The package for the electron element according to claim 3, wherein the via has a cross-sectional area perpendicular to the penetration direction which is generally constant from a top end position to a bottom end position of the via.

5. The package for the electron element according to claim 1, wherein the base substrate is produced by stacking a plurality of ceramic sheets and firing the ceramic sheets stacked, and the projecting part has a length not less than a thickness of one of the plurality of ceramic sheets.

6. An electronic component comprising the package for the electron element according to claim 1, and the electron element mounted on the package for the electron element, wherein the electron element is accommodated in the cavity defined inside the frame body of the package for the electron element and arranged above the via.
